(19) United States
(12) Patent Application Publication
(10) Pub. No.: US 2025/0374466 A1
(43) Pub. Date: Dec. 4, 2025

(54) POWERED MODULAR ACCESSORY WALL PANELS

(71) Applicant: Ford Global Technologies, LLC, Dearborn, MI (US)

(72) Inventors: Ming Hong Choi, LaSalle (CA); Blaise Nugent, Brighton, MI (US); Matthew B. Rutman, Westland, MI (US)

(21) Appl. No.: 18/677,064

(22) Filed: May 29, 2024

(51) Int. Cl. H05K 7/02; H02G 5/02

(52) U.S. Cl. CPC H05K 7/02; H02G 5/02

(57) ABSTRACT

An assembly comprises a plurality of modular base plates that are selectively attachable to a support surface. Each modular base plate includes a plurality of mounting apertures configurable to receive mounting feet from one or more accessories, a plurality of bus bars, and at least one power interface aperture. A power connection interface is associated with one modular base plate, wherein the power connection interface provides power from a power source to all modular base plates of the plurality of modular base plates via the plurality of bus bars.

### TECHNICAL FIELD

This disclosure relates generally to a powered modular base plate assembly, and more particularly, to a powered modular base plate configuration that can be attached to a supporting structure in a non-vehicle application such that accessories can be easily and quickly interchanged between being mounted to a base plate in a vehicle application and being mounted to a base plate in a non-vehicle application.

### BACKGROUND

Vehicles transport various types of cargo including accessories, such as bins, containers, and tools, for example. The accessories can vary in size/shape and may require a power source. Support surfaces in a vehicle cargo area or other type of work area may be configured to securely support the accessories.

### SUMMARY

In some aspects, the techniques described herein relate to an assembly, including: a plurality of modular base plates that are selectively attachable to a support surface; wherein each modular base plate includes a plurality of mounting apertures configurable to receive mounting feet from one or more accessories, a plurality of bus bars, and at least one power interface aperture, and a power connection interface associated with one modular base plate, wherein the power connection interface provides power from a power source to all modular base plates of the plurality of modular base plates via the plurality of bus bars.

In some aspects, the techniques described herein relate to any of the described assemblies, and further including wherein the plurality of bus bars comprises a plurality of positive bus bars and a plurality of negative bus bars, wherein the plurality of positive bus bars and the plurality of negative bus bars each extend from one edge of each modular base plate to an opposite edge of each modular base plate.

In some aspects, the techniques described herein relate to any of the described assemblies, and further including wherein the plurality of positive bus bars and the plurality of negative bus bars are arranged in a grid pattern with each positive bus bar overlapping at least one negative bus bar at an intersection.

In some aspects, the techniques described herein relate to any of the described assemblies, and further including an insulation layer between each positive bus bars and each negative bus bars at each intersection.

In some aspects, the techniques described herein relate to any of the described assemblies, and further including wherein positive bus bars and negative bus bars are off-set from each other at each intersection.

In some aspects, the techniques described herein relate to any of the described assemblies, and further including wherein the plurality of bus bars are at least partially embedded with each modular base plate.

In some aspects, the techniques described herein relate to any of the described assemblies, and further including the plurality of bus bars are adhered to a rear facing side of each modular base plate.

In some aspects, the techniques described herein relate to any of the described assemblies, and further including wherein each modular base plate comprises an outer peripheral edge that includes a plurality of mount features, wherein a first mount feature from the plurality of mount features on a first modular base plate of the plurality of modular base plates overlaps a second mount feature from a second modular base plate of the plurality of modular base plates to secure the first modular base plate and the second modular base plate together.

In some aspects, the techniques described herein relate to any of the described assemblies, and further including a plurality of fasteners that are used to secure overlapping first and second mount features together.

In some aspects, the techniques described herein relate to any of the described assemblies, and further including a plurality of electrical contacts formed about the outer peripheral edge of each modular base plate, wherein the plurality of electrical contacts for each modular base plate comprise a positive electrical contact positioned on one side of each mount feature and a negative electrical contact positioned on an opposite side of each mount feature.

In some aspects, the techniques described herein relate to any of the described assemblies, and further including wherein: the first mount feature and the second mount feature comprise tabs that extend outwardly of the outer peripheral edge in a direction toward an adjacent modular base plate, and wherein each modular base plate includes: a first protrusion extending outwardly of the outer peripheral edge on the one side of each mount feature in a direction toward an adjacent modular base plate; and a second protrusion extending outwardly of the outer peripheral edge on the opposite side of each mount feature in the direction toward the adjacent modular base plate; and wherein the positive electrical contact is associated with the first protrusion and the negative electrical contact is associated with the second protrusion.

In some aspects, the techniques described herein relate to any of the described assemblies, and further including wherein: positive electrical contacts on the outer peripheral edge of each modular base plate are only aligned with, and engageable with, positive electrical contacts on the outer peripheral edge of each adjacent modular base plate; and wherein negative electrical contacts on the outer peripheral edge of each modular base plate are only aligned with, and engageable with, negative electrical contacts on the outer peripheral edge of each adjacent modular base plate.

In some aspects, the techniques described herein relate to any of the described assemblies, and further including wherein, when a set of modular base plates from the plurality of modular base plates are attached to each other at overlapping first and second mount features, a modular plate structure is formed with exposed outer edges that include both positive electrical contacts and negative electrical contacts, and wherein the power connection interface comprises one of the positive electrical contacts at the exposed outer edges and one of the negative electrical contacts at the exposed outer edges that are immediately adjacent to each other to form a pair of power connection contacts.

In some aspects, the techniques described herein relate to any of the described assemblies, and further including wherein power connection interface is provided anywhere about an entire periphery of the modular plate structure where there are a pair of power connection contacts, and wherein the pair of power connection contacts are connectable to the power source which comprises a single power supply that supplies power to all modular base plates in the modular plate structure.

In some aspects, the techniques described herein relate to any of the described assemblies, and further including wherein each modular base plate further includes a plurality of locking apertures, and wherein, a plurality of sub-groups of apertures are formed on each modular base plate, wherein each sub-group of apertures comprises a predetermined pattern that includes at least one mounting aperture from the plurality of mounting apertures, at least one locking aperture from the plurality of locking apertures, and the at least one power interface aperture.

In some aspects, the techniques described herein relate to a method, including: providing a plurality of modular base plates that are selectively attachable to a support surface, wherein each modular base plate includes a plurality of mounting apertures configurable to receive mounting feet from one or more accessories, a plurality of bus bars, and at least one power interface aperture; forming a modular plate structure by two more modular base plates to each other, wherein the modular plate structure has exposed outer edges that include a plurality of pairs of electrical contacts, with each pair of electrical contacts comprising at least one positive electrical contact and at least one negative electrical contact; connecting a power source to a power connection interface comprising any pair of electrical contacts located anywhere about an entire periphery of the modular plate structure; and powering all modular base plates in the modular plate structure with the power source via the plurality of bus bars.

In some aspects, the techniques described herein relate to any of the described methods, and further including wherein the plurality of bus bars comprises a plurality of positive bus bars and a plurality of negative bus bars, and including: extending each positive bus bar and negative bus bar from one edge of each modular base plate to an opposite edge of each modular base plate; and arranging positive bus bars and negative bus bars in a grid pattern with each positive bus bar overlapping at least one negative bus bar at an intersection.

In some aspects, the techniques described herein relate to any of the described methods, and further including providing an insulation layer between the positive bus bars and the negative bus bars at each intersection.

In some aspects, the techniques described herein relate to any of the described methods, and further including off-setting the positive bus bars and the negative bus bars from each other at each intersection.

In some aspects, the techniques described herein relate to any of the described methods, and further including overmolding the plurality of bus bars into each modular base plate such that the plurality of bus bars are at least partially embedded with each modular base plate.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### BRIEF DESCRIPTION OF THE FIGURES

The various features and advantages of the disclosed examples will become apparent to those skilled in the art from the detailed description. The figures that accompany the detailed description can be briefly described as follows:

FIG. 1A illustrates a perspective view of a vehicle having a cargo area equipped with base plates that can be used to secure an accessory according to an exemplary aspect of the present disclosure.

FIG. 1B is similar to FIG. 1A but shows a different type of vehicle.

FIG. 2 is a schematic illustration of an accessory that is mountable to a base plate.

FIG. 3 is a perspective view of a modular base plate as mounted to wall studs.

FIG. 4 a front view of the modular base plate of FIG. 3.

FIG. 5A is a side view of mount features on peripheral edges of adjacent modular base plates.

FIG. 5B is a top view of the modular base plates of FIG. 5A as attached to each other.

FIG. 6A is a top perspective view of alignment features on a peripheral edge of one type of modular base plate.

FIG. 6B is a bottom perspective view of alignment features on a peripheral edge of another type of modular base plate that attaches to the modular base plate of FIG. 6A.

FIG. 7 is a top view of four modular base plates being attached to each other.

FIG. 8 is a perspective view of the base plates of FIG. 7 as mounted to wall studs.

FIG. 9 shows an alternate arrangement of modular base plates.

FIG. 10 is a front view of a modular plate structure comprised of a plurality of base plates that are powered from a power source.

FIG. 11 is a magnified section view of an electrical connection interface that is positioned along a peripheral edge of each modular base plate.

FIG. 12 is a schematic view of one example of a bus bar assembly.

FIG. 13 is a schematic view of another example of a bus bar assembly.

FIG. 14A is a top perspective view of an electrical connection interface that is positioned along a peripheral edge of each modular base plate.

FIG. 14B is a bottom perspective view of the electrical connection interface of FIG. 14A.

FIG. 15 is a front view of one example of a modular plate structure comprised of a plurality of base plates that are powered from a power source.

FIG. 16 is a front view of another example of a modular plate structure comprised of a plurality of base plates that are powered from a power source.

### DETAILED DESCRIPTION

The subject disclosure provides a modular base plate mounting structure having a plurality of mounting apertures to which various types of accessory structures can be selectively secured via an attachment interface. The attachment interface includes mounting feet or cleats that are inserted into the mounting apertures. The base plates can be mounted outside of a vehicle to a floor structure or a wall structure in various configurations. The modular base plate mounting structure provides a mounting interface that is interchangeable between a vehicle and a non-vehicle work place.

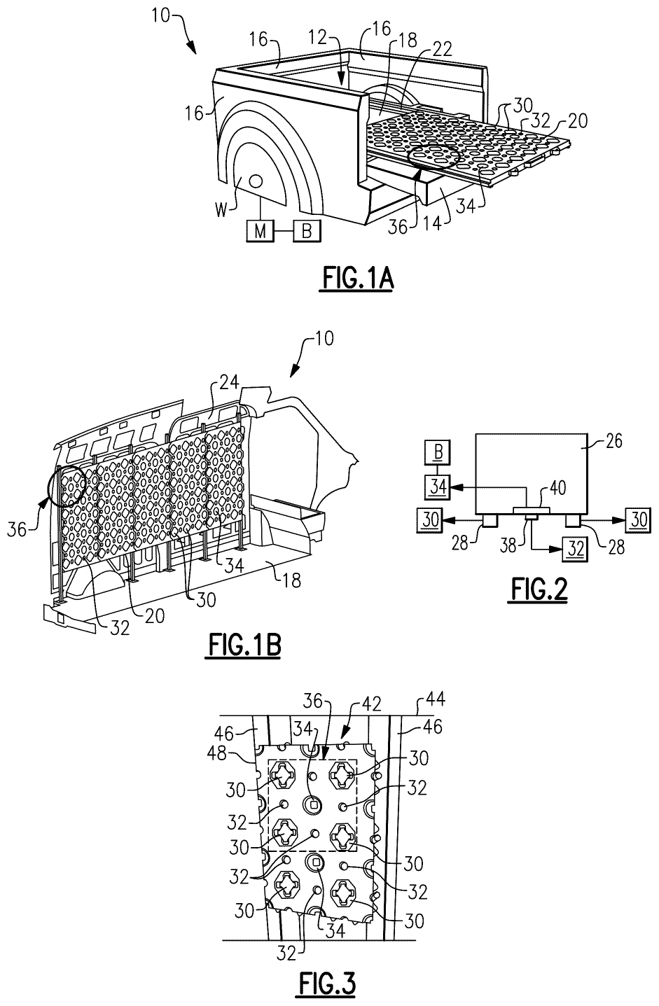

FIGS. 1A and 1B show a vehicle 10 that includes a cargo area 12 that is aft of a passenger compartment (not shown). A tailgate 14 is moveable between open and closed positions to enclose one end of the cargo area 12. The cargo area 12 is further defined by side walls 16 and a floor 18 that supports one or more base plates 20. In this example, the base plates 20 are slidable out of the cargo area 12 on a rail or track system 22 such that the base plates 20 can be removed from the cargo area 12 when the tailgate 14 is in the open position.

In this example, the vehicle 10 is a pickup truck. However, the vehicle 10 could be another type of vehicle in another example, such as a car, van, sport utility vehicle, etc. FIG. 1B shows an example of a vehicle 10 that comprises a van that incorporates one or more base plates 20 onto an upright wall 24.

In one example, the vehicle 10 includes an electrified powertrain capable of applying a torque from an electric machine M (e.g., an electric motor) to drive a least one set of wheels W. The vehicle 10 can include a traction battery pack B, which powers the electric machine M and, potentially, other electrical loads of the vehicle 10. The example vehicle 10 may be an electrified vehicle and, in particular, a battery electric vehicle (BEV). In another example, the vehicle 10 could be another type of electrified vehicle, such as a plug-in hybrid electric vehicle (PHEV), or a conventional vehicle.

The base plates 20 are configured to provide an accessory attachment system where various different types of accessories 26 with mounting feet/cleats 28 that can be selectively attached and detached from the base plates 20. For example, as shown in FIGS. 1A and 1B, the base plates 20 are formed with a plurality of mounting apertures 30 that are configured to receive the mounting feet/cleats 28 of attachment accessories 26. In one example, the base plates 20 also include locking apertures 32 to lock the accessory 26 to the base plate 20 as needed, and power interface apertures 34 to provide power to the accessories 26 as needed.

As shown in FIG. 2, an example accessory 26 includes one or more mounting feet or cleats 28. The accessory 26 can engage the base plate 20 by inserting each mounting cleat 28 into a single mounting aperture 30 to provide a mechanical connection interface. The mounting apertures 30 are spaced upwardly from the floor 18 or side walls 16, 24 by an open gap such that the mounting cleats 28 can be easily inserted into the base plate 20.

As discussed above, the base plate 20 includes a plurality of apertures. In one example, the plurality of apertures are divided into sub-groups 36 of apertures that include at least one type of each different aperture 30, 32, 34. In one example, the power interface apertures 34 and locking apertures 32 of the base plate 20 are spaced apart and separate from each other and from the mounting apertures 30. In one example, the apertures 30, 32, 34 can have shapes and/or sizes that are different from each other. The sub-groups 36 of apertures 30, 32, 34 are provided at multiple locations on the base plate 20, and are formed in a desired pattern on the base plate 20 to allow for the accessories 26 to be mounted in various different locations as needed. In one example, the mounting apertures 30 are formed to have a diamond shape and are larger in size than the power apertures 34 and locking apertures 32.

In one example, the sub-group 76 comprises mounting apertures 30 that are formed in a four corner pattern with a center power aperture 34 between the four corners, and with locking apertures 32 between adjacent mounting apertures 30. This pattern provides for easy and quick connect/disconnect.

In one example, the accessory 26 includes at least one lock 38 that is separate from the mounting feet/cleats 28. Thus, the various accessories 26 can be secured to the vehicle 10 by engaging one or more of the mounting apertures 30 in the base plates 20 via the mounting cleats 28 and then actuating the lock 38 into one of the locking apertures 32. The accessories 26 can comprise, for example, a lockable storage box that holds clothing, tools, a refrigerator, etc. The accessory 26 could also be a lidded lockable container that includes a compartment for storing power tools or other items that require data connection or power connection via the power interface apertures 34. In this configuration, the accessory 26 includes a power interface 40, as schematically shown in FIG. 2 that interacts with the power interface apertures 34. This would allow devices within the accessory 26 to be powered from a vehicle power supply such as the battery pack B, 12V vehicle power, or other power sources via a variety of connections/outlets, for example. Examples of such a power interface connection between an accessory and a base plate can be found in application Ser. Nos. 17/716,053 and 17/716,048, which were both filed on Apr. 8, 2022, and which are assigned to the assignee of the subject application, and which are herein incorporated by reference in their entirety.

As discussed above, the base plates 20 with the apertures 30, 32, 34 can be mounted to the walls 16, 24 or the floor 18 in the cargo area 12 in a first base support application. The subject disclosure provides for this type of base plate mounting configuration, i.e., a second base support application, that can be used on walls 44 (FIG. 3) in a stationary, non-vehicle application, e.g., a utility trailer, a garage or a shop, to allow accessories to be moved back and forth between the vehicle 10 and a permanent work area.

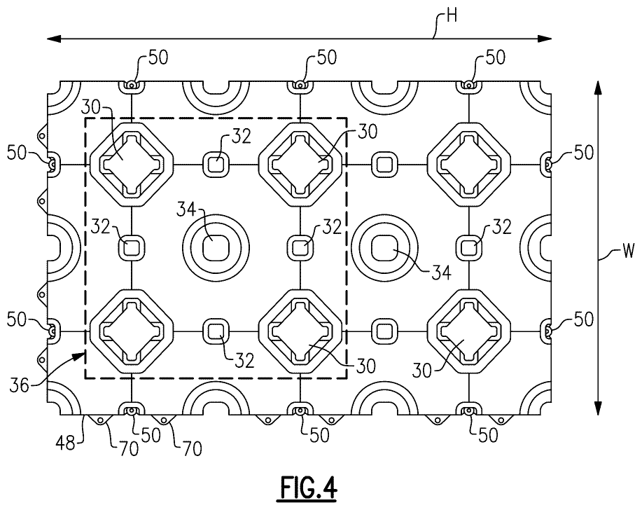

In one example shown in FIGS. 3-4, a modular base plate 42 is shown that can be mounted directly to wall studs 46, for example. In one example, each modular base plate 42 is sized as a sixteen inch width W by twenty-four inch height H (16″×24″) plate, which is able to be mounted on sixteen inch (16″) and twenty-four inch (24″) stud spacing as typically used in construction. In this example, each modular base plate 42 includes mounting apertures 30 with a diamond shape, locking apertures 32, and power interface apertures 34 on 8″ spacing; however, other spacing configurations could also be used. The plurality of apertures are comprised of the sub-groups 36 that each comprise a predetermined pattern that includes at least one mounting aperture 30, at least one locking aperture 32, and at least one power interface aperture 34, and wherein the predetermined pattern is the same for the first base support application and the second base support application. This allows accessories 26 to be selectively detached from one type of base plate 20 or 42 and then selectively attached to the other of the type of base plate 20 or 42.

In one example, for each sub-group 36, the at least one mounting aperture 30 comprises a plurality of mounting apertures 30, the at least one locking aperture 32 comprises a plurality of locking apertures 32, and the at least one power interface aperture 34 comprises a single power interface aperture 34. This type of configuration allows for accessories 26 to be easily installed on the plates in multiple different orientations and rotational positions. In one example, each sub-group 36 includes four mounting apertures 30, four locking apertures 32, and a single power interface aperture 34.

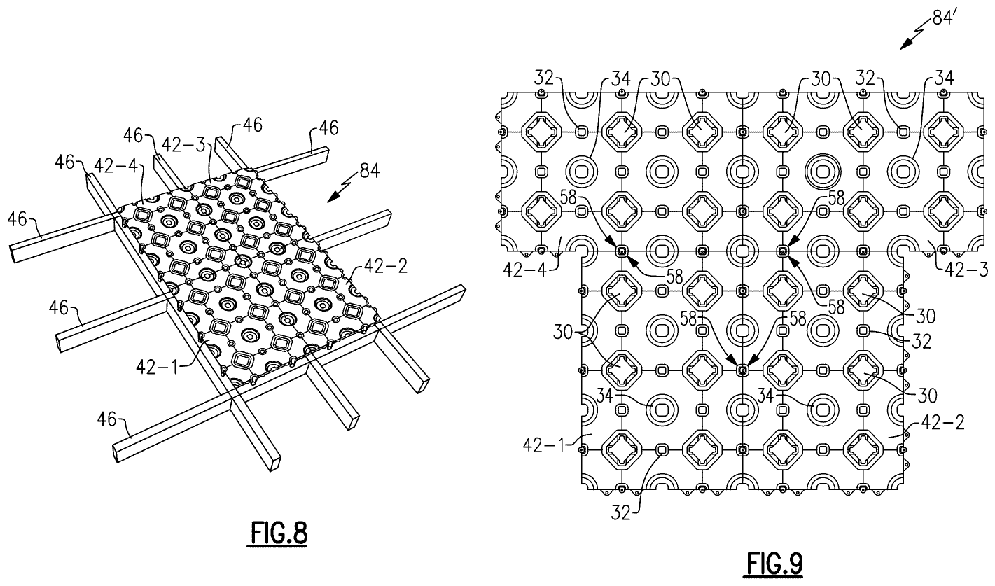

In one example, the base plates 42 have tiling capability (FIGS. 8-9) for proper spacing and the base plates 42 overlap such that fasteners are fastened through aligned bosses on overlapping peripheral edges of adjacent plates such that the base plates 42 are attached directly to the studs 46. This will be discussed in greater detail below.

FIG. 4 shows one example where each modular base plate 42 has an outer peripheral edge 48 that includes a plurality of mount features 50, wherein a first mount feature 50 on a modular base plate 42 overlaps a second mount feature 50 from an adjacent modular base plate 42 to secure two modular base plates 42 together as shown in FIGS. 5A-5B. In one example, a plurality of fasteners 52 are used to secure overlapping first and second mount features 50 together such that adjacent modular base plates 42 are attached directly to the wall studs 46.

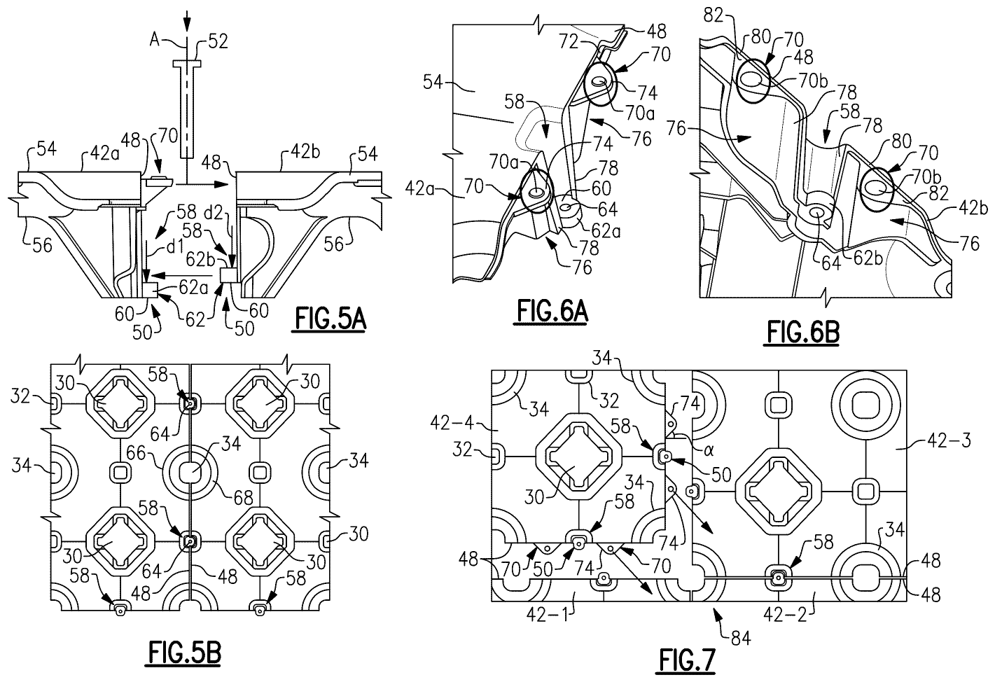

As shown in FIGS. 5A-5B, each modular base plate 42 has an outward surface 54, e.g., an accessory support surface, and an inward surface 56 facing opposite the outward surface 54. In one example, the mount features 50 are formed in recessed pocket areas 58 (see FIG. 6A) that are open to the outward surface 54 and have a distal end 60 located adjacent the inward surface 56. Thus, each pocket area 58 has a depth or length that extends in a direction from the outward surface 54 toward the inward surface 56.

In one example, the plurality of mount features 50 comprise bosses 62 that extend outwardly of the outer peripheral edge 48 in a direction toward an adjacent plate, and which are spaced apart from the outward accessory support surface 54 in a direction toward the inward surface 56. In this example, there are two types of modular base plates 42. A first type of modular base plate 42a has a first boss 62a located at first depth d1 in the pocket area 58 and a second type of modular base plate 42b has a second boss 62b located at second depth d2 in the pocket area 58 that is different than the first depth d1. This offset between the bosses 62a, 62b allows the bosses to overlap each other as shown in FIG. 5B such that the fasteners 52 can be inserted along an insertion axis A through aligned openings 64 formed in the bosses 62a, 62b.

As such, in this example, one mount feature 50 from the first type of modular base plate 42a and another mount feature 50 from the second type of modular base plate 42b are offset from each other in a direction along the insertion axis A of the fastener 52. This fastening arrangement also provides for alignment of the modular base plates 42a, 42b relative to each other. For example, the modular base plates 42, along the peripheral edge 48, may have a portion of one aperture that would need to be aligned with a remaining portion of a corresponding aperture on an adjacent plate. FIG. 5B shows an example where the peripheral edge 48 of the first modular base plate 42a includes one portion 66 of a power interface aperture 34 and the peripheral edge 48 of the second modular base plate 42b includes a remaining portion 68 of the power interface aperture 34. When the fastener 52 is inserted through the aligned openings 64 in the bosses 62a, 62b, the portions 66, 68 are aligned with each other to form a complete power interface aperture 34.

In one example, only partial power interface apertures 34 are located along the peripheral edges 48 of the modular base plates 42, and the mounting apertures 30 and locking apertures 32 are always spaced inward of the peripheral edge 48.

In one example shown in FIGS. 6A-6B, the modular base plates 42 may also include a plurality of alignment features 70, wherein alignment features 70 for one of the first modular base plate 42a and the second modular base plate 42 comprise female structures and alignment features 70 for the other of the first modular base plate 42a and the second modular base plate 42b comprise male structures that fit into corresponding female structures.

In one example, each modular base plate 42 includes at least two alignment features 70 associated with each mount feature 50. In one example, one alignment feature 70 is on one side of each mount feature 50 and another alignment feature 70 is on an opposite side of each mount feature 50.

As discussed above, the bosses 62a, 62b are formed in recessed pocket areas 58 that are open to the outward surface 54. In one example, the first type of modular base plate 42a with the first boss 62a has male alignment features 70a and the second type of modular base plate 42b with second boss 62b has female alignment features 70b. In one example, the male alignment features 70a are provided on a recessed lip area 72 along the peripheral edge 48 of the first type of modular base plate 42a. In one example, one protruding portion 74 extends outward of the recessed lip area 72 on each side of the pocket area 58 in a direction toward an adjacent base plate. In one example, the male alignment features 70a comprise protrusions, tabs, or buttons that extend upward from a surface of the respective protruding portion 74 in a direction toward the outward surface 54 of the first type of modular base plate 42a.

In one example, the peripheral edge 48 of the second type of modular base plate 42b includes recessed pocket areas 76 that are on each side of the pocket area 58. Walls 78 separate the recessed pocket areas 76 from the pocket area 58. In one example, a flange portion 80 extends outward of the peripheral edge 48 of the second type of modular base plate 42b in a direction toward the first type of modular base plate 42a. This flange portion 80 covers an upward end of the recessed pocket areas 76. In one example, the female alignment features 70b are formed as recesses in an inward facing surface 82 of the flange portion 80. When the bosses 62a, 62b are aligned with each other, the flange portions 80 on either side of the pocket area 58 overlap the recessed lip area 72 on each side of the pocket area 58 such that the female alignment features 70b fit into the male alignment features 70a.

FIG. 7 shows an example where four modular base plates 42-1, 42-2, 42-3, and 42-4 are fit together to form a modular wall structure 84. In the example shown, the modular base plates 42-1, 42-2, 42-3 have already been fit together and only the last corner plate 42-4 needs to be installed. In one example, the edges of the protruding portions 74 of the first type of modular base plate 42a, e.g., corner plate 42-4, extend at a predetermined angle a such that this corner plate 42-4 can be easily installed after the other plates 42-1, 42-2, 42-3 are already fixed in place. In one example, the predetermined angle a comprises a forty-five degree angle extending in a direction normal to the peripheral edge 48; however, other configurations could also be used.

FIG. 8 shows a final installation position of the four modular base plates 42-1, 42-2, 42-3, and 42-4 as attached to a plurality of wall studs 46.

FIG. 9 shows another example of four modular base plates 42-1, 42-2, 42-3, and 42-4 that can be arranged in an alternate configuration of a modular wall structure 84′.

Additional plates can be tiled together on a wall to create a larger modular wall structure for mounting larger accessories, or simply to cover a larger area. The plates can be installed “horizontally” or “vertically” or a mixture of both “horizontally” or “vertically”, due to the plurality of mount features around the perimeter which do not all need to be used.

In one example, the plate material comprises a composite plastic material that is strong enough to hold large loads but also slightly flexible to resist cracking when dropped, or breaking, when fasteners are tightened. Examples of composite plastic materials include, for example, fiber-reinforced composites, carbon fiber composites, glass fiber composites, etc.

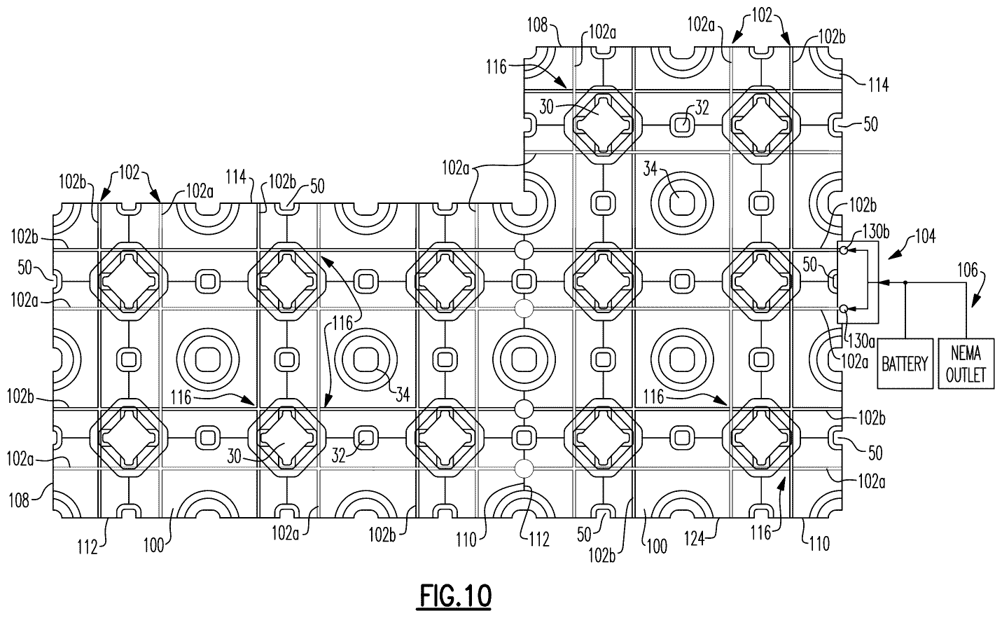

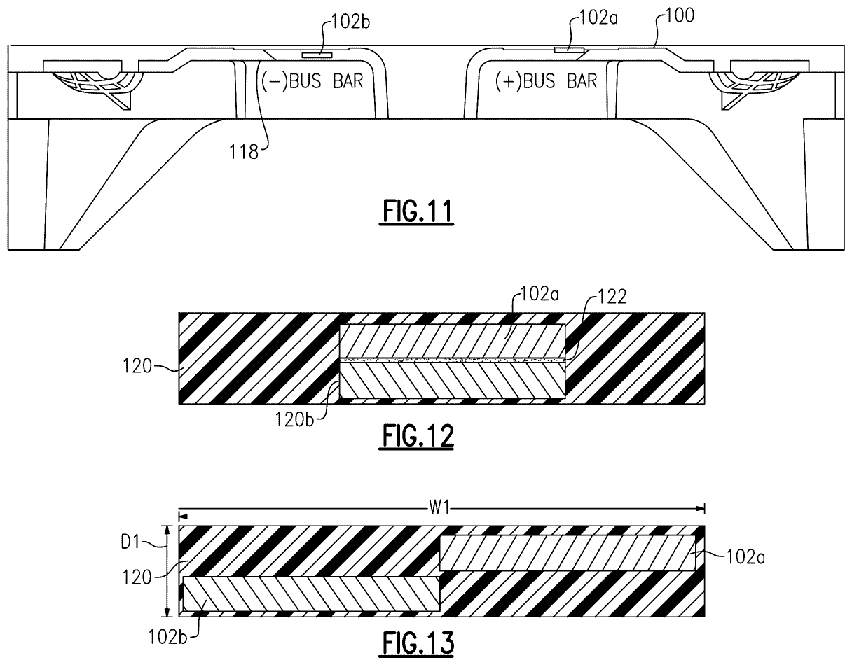

FIGS. 10-16 show examples of powered base plate configurations. In one example, a plurality of modular base plates 100 are selectively attachable to a support surface, such as wall studs 46 for example, in a selected one of a plurality of different arrangements (see FIGS. 11, 15, and 16). Each modular base plate 100 includes a plurality of mounting apertures 30 configurable to receive mounting feet/cleats 28 from one or more accessories 26, a plurality of bus bars 102, and at least one power interface aperture 34. The modular base plate 100 may also include one or more locking apertures 32. In one example, a power connection interface 104 is associated with one of the modular base plates 100, wherein the power connection interface 104 provides power from a power source 106 to all modular base plates 100 in each base plate arrangement.

In one example, the plurality of bus bars 102 comprises a plurality of positive bus bars 102a and a plurality of negative bus bars 102b. In one example, the positive bus bars 102a and the negative bus bars 102b each extend from one edge of each modular base plate 100 to an opposite edge of each modular base plate 100. Each modular base plate 100 extends in a longitudinal direction from a first edge 108 to a second edge 110, and each modular base plate 100 extends in a lateral direction from a third edge 112 to a fourth edge 114. Some of the positive bus bars 102a and the negative bus bars 102b extend in the longitudinal direction from the first edge 108 to the second edge 110, and some of the positive bus bars 102a and the negative bus bars 102b extend in the lateral direction from the third edge 112 to the fourth edge 114. In this example, the bus bar arrangement comprises a grid pattern with positive bus bars 102 overlapping negative bus bars 102b at a plurality of intersections 116.

As shown in FIG. 11, the bus bars 102a, 102b are at least partially embedded within a body 120 (FIG. 12) of the of the base plates 100 themselves. As discussed above, the base plates 100 are made from a composite plastic material, for example. In one example, the bus bars 102a, 102b are overmolded within the composite plastic material to form the base plates 100. Any type of molding process can be used, such as insert molding, two-shot molding, etc. Optionally, the bus bars 102a, 102b can be adhered to a rear surface 118 of the base plates 100.

The positive bus bars 102a and the negative bus bars 102b cannot touch each other at the intersections 116 such that there will be no possibility of short circuiting. FIGS. 12 and 13 disclose examples of non-contact at the intersections 116.

FIG. 12 shows a section of the molded plastic body 120 of the base plate 100 at the intersection 116. In this example, an insulation layer 122 is between each positive bus bar 102b and each negative bus bar 102b at each intersection 116. In one example, the insulation layer 122 comprises a thin film insulation layer.

FIG. 13 also shows a section of the molded plastic body 120 of the base plate 100 at the intersection 116. In this example, the positive bus bars 102 and negative bus bars 102b are off-set from each other at each intersection 116 in at least one direction. The offset can be in one direction or multiple directions. FIG. 13 shows an example where the positive bus bars 102 and negative bus bars 102b are at least partially offset from each other in a height direction DI and in a width direction D2. Thus, each bar of different polarity is on a different height and insulated from each other by way of material from the molded plastic body 120.

In one example, each modular base plate 100 comprises an outer peripheral edge 124 that includes a plurality of mount features 50 as described above. Mount features 50 on one base plate 100 overlap mount features 50 from an adjacent modular base plate 100 to secure base plates 100 together.

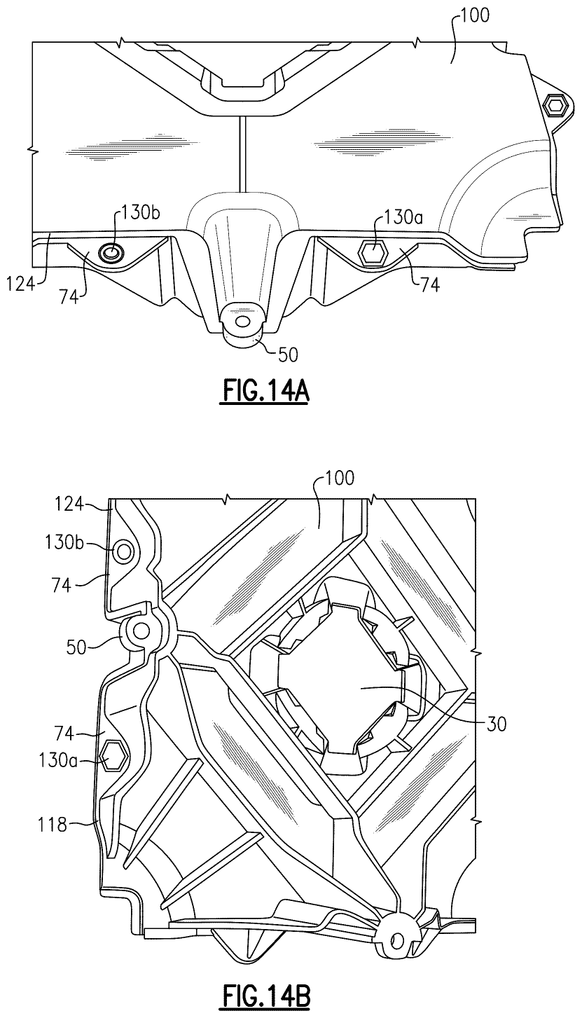

As shown in FIG. 10 and FIGS. 14A-B, a plurality of electrical contacts 130 are formed about the outer peripheral edge 124 of each modular base plate 100. The plurality of electrical contacts 130 for each modular base plate 100 comprise a positive electrical contact 130a positioned on one side of each mount feature 50 and a negative electrical contact 130b positioned on an opposite side of each mount feature as shown in FIG. 14A. The positive electrical contacts 130a and the negative electrical contacts 130b are exposed portions that mate with positive electrical contacts 130a and the negative electrical contacts 130b on adjacent plates 100. The positive electrical contacts 130a are electrically connected to the positive bus bars 102a and the negative electrical contacts 130b are electrically connected to the negative bus bars 102b.

In one example, the positive electrical contacts 130a and the negative electrical contacts 130b are provided on the protruding portions 74 that extend outwardly of the outer peripheral edges 124 around an entire periphery of each plate 100. The positive electrical contacts 130a on the outer peripheral edge 124 of each modular base plate 100 are only aligned with, and engageable with, positive electrical contacts 130a on the outer peripheral edge 124 of each adjacent modular base plate 100. The negative electrical contacts 130b on the outer peripheral edge 124 of each modular base plate 100 are only aligned with, and engageable with, negative electrical contacts 130b on the outer peripheral edge 124 of each adjacent modular base plate 100.

By using the protruding portions 74, the electrical contacts 130 can easily be built-in to the edges of the plate body 120 to enable electrical conductivity throughout the base plate 100. In one example as shown in FIG. 14B, at each mount location 50 the electrical contacts 130a, 130b are exposed at the rear surface 118 of the protruding portion 74. The underside 118 of mating plates 100 show the electrical contacts 130a, 130b that mate to tabs from connected, daisy chained plates. In one example, the electrical contacts 130a, 130b are in the form of bus bars 102a, 102b that are within the molded structure of the plates 100, and that are arranged in a way to prevent improper installation and facilitate case of installation. This also allows for a daisy chain connection between adjacent plates 100. Electrical conductivity is thus simultaneously supplied to connected plates 100 when mechanical connections at the overlapping mount features 50 are connected. As such, these overlapping tabs can be mechanically keyed to enable case of electrical installation when assembling a plurality of plates together.

When a set of modular base plates 100 are attached to each other at overlapping first and second mount features 50, a modular multi-plate structure is formed with exposed outer edges that are not connected to adjacent plates as shown in FIGS. 10, 15, and 16. These exposed outer edges include both positive electrical contacts 130a and negative electrical contacts 130 that are located about an entire outer periphery of the modular multi-plate structure.

In one example, the power connection interface 104 comprises one of the positive electrical contacts 130a at the exposed outer edges and one of the negative electrical contacts 130b at the exposed outer edges that are immediately adjacent to each other to form a pair of power connection contacts as shown in FIG. 10. Thus, the power connection interface 104 can be selected by the user to be positioned anywhere about the entire periphery of the modular multi-plate structure where there are a pair of power connection contacts. The pair of power connection contacts are connectable to the power source 106 which comprises a single power supply that supplies power to all modular base plates 100 in the modular multi-plate structure. In one example, the power source 106 can come from a single power supply 134, e.g. a battery, that connects to one set of contacts 130a, 130b on the plate, or the single power supply can comprise an outlet connection 136 to an electrical system. The power can be either DC or AC power. In one example, a bracket (not shown) with electrical connections for the power source connection can be mated to any panel with exposed contacts.

In one example, the power connection interface 104 comprises a snap-in connector to electrically connect the power source 106 to the electrical contacts 130a, 130b. Any type of snap-in electrical connector can be used.

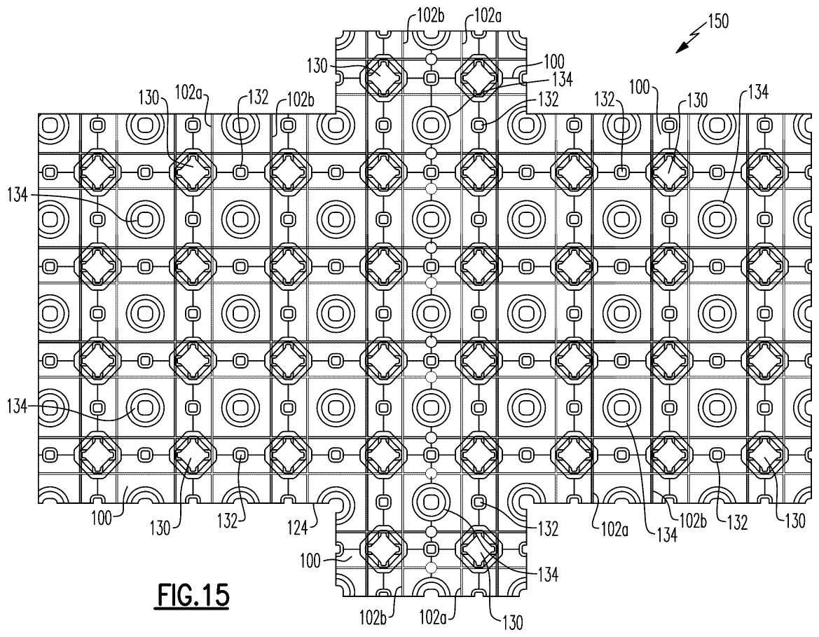

FIG. 15 shows one example of a multi-plate structure 150 comprised of a plurality of plates 100. Any additional plates that are connected together will conduct electricity from the power source 106 in a daisy chained configuration. Vertical and horizontal orientations are compatible, which allows for ease of installation without limiting the user to a certain installation method.

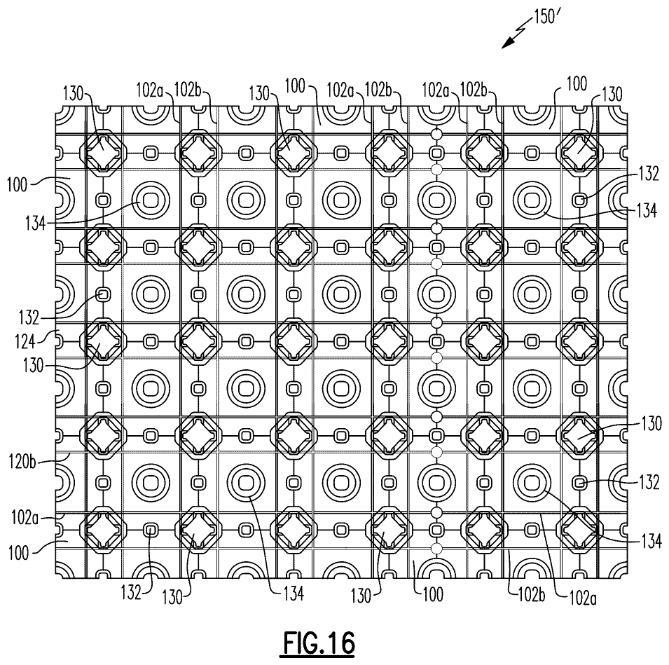

FIG. 16 shows another example of a multi-plate structure 150′ comprised of a plurality of plates 100.

In one example, a method comprises: providing a plurality of modular base plates 100 that are selectively attachable to a support surface, wherein each modular base plate includes a plurality of mounting apertures 130 configurable to receive mounting feet from one or more accessories 26, a plurality of bus bars 102, and at least one power interface aperture 34; forming a modular plate structure by two more modular base plates 100 to each other, wherein the modular plate structure has exposed outer edges that include a plurality of pairs of electrical contacts 130, with each pair of electrical contacts comprising at least one positive electrical contact 130a and at least one negative electrical contact 130b; connecting a power source 106 to a power connection interface 104 comprising any pair of electrical contacts located anywhere about an entire periphery of the modular plate structure; and powering all modular base plates 100 in the modular plate structure with the power source 106.

In one example, the method may include, extending each positive bus bar 102a and negative bus bar 102b from one edge of each modular base plate to an opposite edge of each modular base plate; and arranging positive bus bars 102a and negative bus bars 102b in a grid pattern with each positive bus bar overlapping at least one negative bus bar at an intersection 116.

In one example, the method may include, providing an insulation layer 122 between the positive bus bars 102a and the negative bus bars 102b at each intersection 116.

In one example, the method may include, off-setting the positive bus bars and the negative bus bars from each other at each intersection.

In one example, the method may include, overmolding the plurality of bus bars 102 into each modular base plate 100 such that the plurality of bus bars are at least partially embedded with each modular base plate.

Traditionally, there has not been power provided to wall mount plates, and users of these systems have needed to use external power sources that are directly and individually connected to an accessory charger or power source. Having to route wires/cords to each powered accessory on a wall plate complicates installation and may occupy additional plugs and outlets due to the need to plug in each accessory regardless of a required total power load. Further, large, interconnected wall setups will encounter a higher voltage drop when using multiple wires/cords, which can degrade system performance.

The subject disclosure provides for a modular base plate assembly where there is less power loss for large wall setups with bus bars as compared to wires in traditional configurations due to higher resistance in wires versus bus bars. The plates have increased rigidity due to metallic bus bars being integrated into the structure of the plates. The mating mechanical tab mount features facilitate an easier, user-friendly installation due to the electrical connections being made in the same step as the mechanical attachment during installation.

The preceding description is exemplary rather than limiting in nature. Variations and modifications to the disclosed examples may become apparent to those skilled in the art that do not necessarily depart from the essence of this disclosure. Thus, the scope of protection given to this disclosure can only be determined by studying the following claims.

What is claimed is:

1. An assembly, comprising:
a plurality of modular base plates that are selectively attachable to a support surface; wherein each modular base plate includes
a plurality of mounting apertures configurable to receive mounting feet from one or more accessories,
a plurality of bus bars, and
at least one power interface aperture, and
a power connection interface associated with one modular base plate, wherein the power connection interface provides power from a power source to all modular base plates of the plurality of modular base plates via the plurality of bus bars.

2. The assembly of claim 1, wherein the plurality of bus bars comprises a plurality of positive bus bars and a plurality of negative bus bars, wherein the plurality of positive bus bars and the plurality of negative bus bars each extend from one edge of each modular base plate to an opposite edge of each modular base plate.

3. The assembly of claim 2, wherein the plurality of positive bus bars and the plurality of negative bus bars are arranged in a grid pattern with each positive bus bar overlapping at least one negative bus bar at an intersection.

4. The assembly of claim 3, including an insulation layer between each positive bus bars and each negative bus bars at each intersection.

5. The assembly of claim 3, wherein positive bus bars and negative bus bars are off-set from each other at each intersection.

6. The assembly of claim 1, wherein the plurality of bus bars are at least partially embedded with each modular base plate.

7. The assembly of claim 1, wherein the plurality of bus bars are adhered to a rear facing side of each modular base plate.

8. The assembly of claim 1, wherein each modular base plate comprises an outer peripheral edge that includes a plurality of mount features, wherein a first mount feature from the plurality of mount features on a first modular base plate of the plurality of modular base plates overlaps a second mount feature from a second modular base plate of the plurality of modular base plates to secure the first modular base plate and the second modular base plate together.

9. The assembly of claim 8, including a plurality of fasteners that are used to secure overlapping first and second mount features together.

10. The assembly of claim 8, including a plurality of electrical contacts formed about the outer peripheral edge of each modular base plate, wherein the plurality of electrical contacts for each modular base plate comprise a positive electrical contact positioned on one side of each mount feature and a negative electrical contact positioned on an opposite side of each mount feature.

11. The assembly of claim 10, wherein:
the first mount feature and the second mount feature comprise tabs that extend outwardly of the outer peripheral edge in a direction toward an adjacent modular base plate, and wherein each modular base plate includes:
a first protrusion extending outwardly of the outer peripheral edge on the one side of each mount feature in a direction toward an adjacent modular base plate; and
a second protrusion extending outwardly of the outer peripheral edge on the opposite side of each mount feature in the direction toward the adjacent modular base plate; and
wherein the positive electrical contact is associated with the first protrusion and the negative electrical contact is associated with the second protrusion.

12. The assembly of claim 10, wherein: positive electrical contacts on the outer peripheral edge of each modular base plate are only aligned with, and engageable with, positive electrical contacts on the outer peripheral edge of each adjacent modular base plate; and wherein negative electrical contacts on the outer peripheral edge of each modular base plate are only aligned with, and engageable with, negative electrical contacts on the outer peripheral edge of each adjacent modular base plate.

13. The assembly of claim 10, wherein, when a set of modular base plates from the plurality of modular base plates are attached to each other at overlapping first and second mount features, a modular plate structure is formed with exposed outer edges that include both positive electrical contacts and negative electrical contacts, and wherein the power connection interface comprises one of the positive electrical contacts at the exposed outer edges and one of the negative electrical contacts at the exposed outer edges that are immediately adjacent to each other to form a pair of power connection contacts.

14. The assembly of claim 13, wherein power connection interface is provided anywhere about an entire periphery of the modular plate structure where there are a pair of power connection contacts, and wherein the pair of power connection contacts are connectable to the power source which comprises a single power supply that supplies power to all modular base plates in the modular plate structure.

15. The assembly of claim 1, wherein each modular base plate further includes a plurality of locking apertures, and wherein, a plurality of sub-groups of apertures are formed on each modular base plate, wherein each sub-group of apertures comprises a predetermined pattern that includes at least one mounting aperture from the plurality of mounting apertures, at least one locking aperture from the plurality of locking apertures, and the at least one power interface aperture.

16. A method comprising:
providing a plurality of modular base plates that are selectively attachable to a support surface, wherein each modular base plate includes a plurality of mounting apertures configurable to receive mounting feet from one or more accessories, a plurality of bus bars, and at least one power interface aperture;
forming a modular plate structure by two more modular base plates to each other, wherein the modular plate structure has exposed outer edges that include a plurality of pairs of electrical contacts, with each pair of electrical contacts comprising at least one positive electrical contact and at least one negative electrical contact;
connecting a power source to a power connection interface comprising any pair of electrical contacts located anywhere about an entire periphery of the modular plate structure; and
powering all modular base plates in the modular plate structure with the power source via the plurality of bus bars.

17. The method of claim 16, wherein the plurality of bus bars comprises a plurality of positive bus bars and a plurality of negative bus bars, and including:
extending each positive bus bar and negative bus bar from one edge of each modular base plate to an opposite edge of each modular base plate; and
arranging positive bus bars and negative bus bars in a grid pattern with each positive bus bar overlapping at least one negative bus bar at an intersection.

18. The method of claim 17, including providing an insulation layer between the positive bus bars and the negative bus bars at each intersection.

19. The method of claim 17, including off-setting the positive bus bars and the negative bus bars from each other at each intersection.

20. The method of claim 19, including overmolding the plurality of bus bars into each modular base plate such that the plurality of bus bars are at least partially embedded with each modular base plate.
